(19) United States
(12) Patent Application Publication
(10) Pub. No.: US 2009/0017615 A1
(43) Pub. Date: Jan. 15, 2009

(54) Method of removing an insulation layer and method of forming a metal wire

(76) Inventors: Jun-Hwan Oh, Namdong-gu (KR); Dong-Chul Hur, Seongnam-si (KR); Hyoung-Sik Kim, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/155,335

(22) Filed: Jun. 3, 2008

(30) Foreign Application Priority Data
Jun. 4, 2007 (KR) 10-2007-0054575

(51) Int. Cl. H01L 21/4763

(52) U.S. Cl. 438/643; 257/E21.495

(57) ABSTRACT

A method of removing an insulation layer pattern covering metal wires includes providing an insulation layer pattern on a substrate, the insulation layer pattern having openings exposing the substrate, forming metal wires in the openings by depositing a barrier layer on inner surfaces of the openings, such that a lower portion of the barrier layer is thinner that an upper portion of the barrier layer, and depositing a metal layer to fill the openings, and performing an etching process with an etching vapor to remove the insulation layer pattern from the substrate to expose the metal wires.

### BACKGROUND OF THE INVENTION

1. Field of the Invention

Embodiments of the present invention relate to a method of forming a metal wire. More particularly, embodiments of the present invention relate to a method of removing an insulation layer covering a metal wire and to a method of forming a metal wire using the same.

2. Description of the Related Art

In semiconductor devices, sizes of patterns, e.g., widths of metal wires in chips, may be decreased in order to realize a higher degree of integration and to enhance operation speed. Such a decrease in pattern size, however, may cause, e.g., a resistance-capacitance (RC) delay due to an increased resistance of the metal wires and a parasitic capacitance between the metal wires.

Attempts have been made to minimize, e.g., the RC delay in the metal wires, by using a damascene process, i.e., filling an opening through an insulation layer with a metal layer, or by forming a dielectric layer having a low dielectric constant between the metal wires. Use of a conventional damascene process and/or the low dielectric constant dielectric layer, however, may have limitations when design rule in semiconductor devices is reduced, e.g., a distance between metal wires of below about 100 nm, thereby not being able to sufficiently reduce the parasitic capacitance between the metal wires.

For example, if wet etching is used to remove an insulation layer covering metal wires formed by a damascene process to have a small distance therebetween, the metal wires may incline toward each other to contact each other due to surface tension of an etching solution, i.e., a surface tension generated by a capillary force due to a small gap between the metal wires, thereby reducing operability and reliability of the semiconductor. Further, since the metal wires are formed by a CVD process, i.e., a process that may cause thinner lower portions than upper portions, the metal wires may be damaged by the wet etching process before complete removal of the insulation layer.

### SUMMARY OF THE INVENTION

Embodiments of the present invention are therefore directed to a method of forming a metal wire, which substantially overcomes one or more of the disadvantages and shortcomings of the related art.

It is therefore a feature of an embodiment of the present invention to provide a method of removing an insulation layer pattern covering a metal wire with a thin barrier layer without damaging the barrier layer.

It is another feature of an embodiment of the present invention to provide a method of forming a metal wire of a semiconductor device by removing an insulation layer pattern covering a metal wire with a thin barrier layer without damaging the barrier layer.

At least one of the above and other features and advantages of the present invention may be realized by providing a method of removing an insulation layer pattern covering metal wires, including providing an insulation layer pattern on a substrate, the insulation layer pattern having openings exposing the substrate, forming metal wires in the openings by depositing a barrier layer on inner surfaces of the openings, such that a lower portion of the barrier layer may be thinner that an upper portion of the barrier layer, and depositing a metal layer to fill the openings, and performing an etching process with an etching vapor to remove the insulation layer pattern from the substrate to expose the metal wires.

Performing the etching process with the etching vapor may include using a hydrogen fluoride vapor. The etching process with the etching vapor may be performed at a temperature of about 25° C. to about 50° C. The etching process with the etching vapor may be performed by providing together a hydrogen fluoride gas as an etching gas and a nitrogen gas as a carrier gas. The etching vapor may include providing the hydrogen fluoride gas and the nitrogen gas at a flow rate ratio of about 1:5 to about 1:300 SLM (standard liters per minute).

Providing the insulation layer pattern may include depositing on the substrate a layer of one or more of a silicon dioxide (SiO₂), a fluorosilicate glass (FSG), a tetraethyl orthosilicate (TEOS) oxide, a silanol (SiOH), a flowable oxide (FOx), a bottom anti-reflective coating (BARC), an anti-reflective coating (ARC), a photoresist (PR), a near-frictionless carbon (NFC), a silicon carbide (SiC), a silicon oxycarbide (SiOC), and a carbon-doped silicon oxide (SiCOH). Forming the metal wires may include forming the barrier layer on inner sidewalls of the openings and on the insulation layer pattern, forming the metal layer pattern on the barrier layer to completely fill the openings and cover the insulation layer pattern, and performing a chemical mechanical polishing (CMP) process to remove portions of the metal layer pattern and the barrier layer to expose an upper surface of the insulation layer pattern. Forming the barrier layer may include depositing one or more of titanium/titanium nitride (Ti/TiN), tantalum/tantalum nitride (Ta/TaN), and tungsten/tungsten nitride (W/WN). Forming the barrier layer may include forming lowermost and uppermost edges of the barrier layer to have a thickness ratio of about 1:3 to about 1:6. After removing the insulation layer pattern, the lowermost and uppermost edges of the barrier layer may have a thickness ratio of about 1:5 to about 1:9.

The method may further include forming an etch-stop layer on the substrate before forming the insulation layer pattern. The method may further include forming a protective layer on the metal wires, the protective layer including one or more of tungsten (W), cobalt (Co), nickel (Ni), nickel phosphate (NiP), nickel tungsten phosphate (NiWP), nickel rhenium phosphate (NiReP), cobalt phosphate (CoP), cobalt tungsten phosphate (CoWP), copper phosphate (CuP), copper nickel phosphate (CuNiP), cobalt copper phosphate (CoCuP), cobalt tungsten (CoW), and copper silicon nitride (CuSiN). Forming the protective layer may include using an electroless plating process. Providing the insulation layer pattern with the openings may include forming the openings such that a distance between two adjacent openings may be about 20 nm to about 90 nm.

At least one of the above and other features and advantages of the present invention may be realized by providing a method of forming metal wires, including forming a first insulation layer pattern on a substrate having a conductive pattern, the insulation layer pattern having openings exposing the conductive pattern, forming a barrier layer on inner surfaces of the openings, such that a lower portion of the barrier layer may be thinner that an upper portion of the barrier layer, forming a metal layer to fill up the openings, the metal layer and the barrier layer defining first metal wires, removing the first insulation layer pattern from the substrate by performing an etching process with an etching vapor to expose the first metal wires, and forming a second insulation layer on the substrate and on the first metal wires, such that a void may be formed between adjacent first metal wires.

The method may further include forming an etch-stop layer having a substantially uniform thickness between the substrate and the first insulation layer. The method may further include forming a protective layer on the first metal wires. The etching process using the etching vapor may be performed using a hydrogen fluoride gas as an etching gas and nitrogen gas as a carrier gas, hydrogen fluoride gas and the carrier gas having a flow rate ratio of about 1:5 to about 1:300 SLM (standard liters per minute).

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1-4 illustrate cross-sectional views of a method of removing an insulation layer covering metal wires in accordance with example embodiments of the present invention;

FIGS. 5-11 illustrate cross-sectional views of a method of forming metal wires of a semiconductor device in accordance with example embodiments of the present invention; and

FIGS. 12-13 illustrate scanning electron microscope (SEM) photographs of a substrate processed according to Example 1 and Comparative Example 1, respectively.

### DETAILED DESCRIPTION OF THE INVENTION

Korean Patent Application No. 10-2007-0054575, filed on Jun. 4, 2007, in the Korean Intellectual Property Office, and entitled: “Method of Removing an Insulation Layer and Method of Forming a Metal Wire,” is incorporated by reference herein in its entirety.

Exemplary embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of elements, layers, and regions may be exaggerated for clarity of illustration. It will also be understood that when an element and/or layer is referred to as being “on” another element, layer and/or substrate, it can be directly on the other element, layer, and/or substrate, or intervening elements and/or layers may also be present. Further, it will be understood that the term “on” can indicate solely a vertical arrangement of one element and/or layer with respect to another element and/or layer, and may not indicate a vertical orientation, e.g., a horizontal orientation. In addition, it will also be understood that when an element and/or layer is referred to as being “between” two elements and/or layers, it can be the only element and/or layer between the two elements and/or layers, or one or more intervening elements and/or layers may also be present. Further, it will be understood that when an element and/or layer is referred to as being “connected to” or “coupled to” another element and/or layer, it can be directly connected or coupled to the other element and/or layer, or intervening elements and/or layers may be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of:” For example, the expression “at least one of A, B, and C” may also include an nth member, where n is greater than 3, whereas the expression “at least one selected from the group consisting of A, B, and C” does not.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of embodiments of the present invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the substrate in the figures is turned over, elements described as “below” or “beneath” other elements or features would then be oriented “above” the other elements or features. Thus, the example term “below” can encompass both an orientation of above and below. The substrate may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

Method of Removing an Insulation Layer Covering a Metal Wire

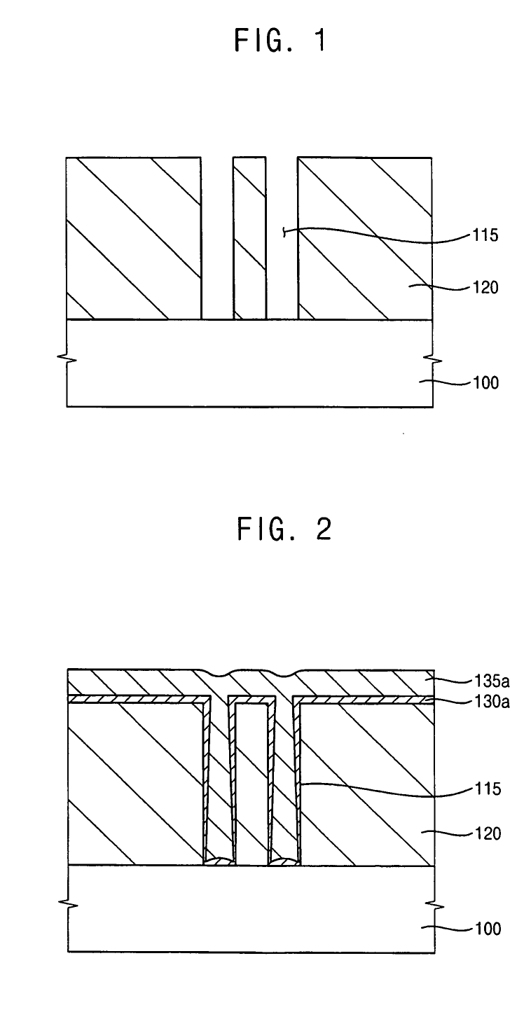

FIGS. 1-4 illustrate cross-sectional views of a method of removing an insulation layer covering a metal wire in accordance with example embodiments of the present invention.

Referring to FIG. 1, an insulation layer pattern 120 having openings 115 may be formed on a substrate 100, so the openings 115 may expose an upper surface of the substrate 100. A distance between two adjacent openings 115 may be about 100 nm or less, e.g., in a range of about 20 nm to about 90 nm. A conductive pattern (not shown) may be formed on the substrate 100, so the conductive pattern may be electrically connected to a metal wire subsequently formed on the substrate 100.

More specifically, an insulation layer (not shown) may be formed on the substrate 100, followed by formation of an etching mask (not shown) on the insulation layer. Portions of the insulation layer exposed through the etching mask may be dry-etched to form the insulation layer pattern 120 having the openings 115 exposing the substrate 100. The openings 115 may extend through the entire insulation layer pattern 120, i.e., from an upper surface of the insulation layer pattern 120 to a lower surface of the insulation layer pattern 120, and may be configured along a vertical direction, i.e., a direction perpendicular to a direction of the substrate 100.

The substrate 100 may be any suitable semiconductor substrate. For example, the substrate 100 may include a silicon substrate, e.g., a single crystalline silicon substrate, a germanium substrate, a silicon-germanium substrate, and so forth.

The insulation layer may include a silicon oxide, e.g., a high-density plasma chemical vapor deposition (HDP-CVD) oxide, borophosphosilicate glass (BPSG) oxide, phosphosilicate glass (PSG), tetraethyl orthosilicate (TEOS), plasma-enhanced chemical vapor deposition (PE-CVD), undoped silicate glass (USG), carbon-doped oxide (CDO), organosilicate glass (OSG), and so forth. For example, the insulation layer may include one or more of silicon dioxide (SiO₂), fluorosilicate glass (FSG), silanol (SiOH), flowable oxide (FOx), a bottom anti-reflective coating (BARC), an anti-reflective coating (ARC), photoresist (PR), near-frictionless carbon (NFC), silicon carbide (SiC), silicon oxycarbide (SiOC), carbon-doped silicon oxide (SiCOH), and so forth. For example, a FOx layer may be formed on the substrate 100 as the insulation layer, and a FSG layer may be formed on the insulation layer as the etching mask.

An etch-stop layer (not shown) may be further formed on the substrate 100 before forming the insulation layer, i.e., the etch-stop layer may be between the substrate 100 and the insulation layer. The etch-stop layer may prevent or substantially minimize damage to the substrate 100 during the etching process, i.e., during formation of the openings 115. The etch-stop layer may include a material having an etching selectivity with respect to the insulation layer. If the etch-stop layer is formed on the substrate 100, a wet etching process may be performed to remove a remaining portion of the etch-stop layer from the substrate 100 after forming the openings 115 through the insulation layer.

Referring to FIG. 2, a barrier layer 130a may be formed on a portion of the substrate 100 exposed by the openings 115 and on the insulation layer pattern 120 to prevent or substantially minimize metal diffusion from a metal layer formed in a subsequent process into the insulation layer pattern 120. More specifically, the barrier layer 130a may be formed conformally on the insulation layer pattern 120 to coat an upper surface of the insulation layer pattern 120, sidewalls of the insulation layer pattern 120, i.e., inner sidewalls of the openings 1115, and portions of an upper surface of the substrate 100 exposed through the openings 115, i.e., an inner bottom surface of the openings 115. The barrier layer 130a may be formed by, e.g., a chemical vapor deposition (CVD) process or a physical vapor deposition (PVD) process, and may include, e.g., a titanium/titanium nitride (Ti/TiN) layer, a tantalum/tantalum nitride (Ta/TaN) layer, a tungsten/tungsten nitride (W/WN) layer, and so forth.

Portions of the barrier layer 130a on inner sidewalls of the openings 115 may have non-uniform thickness. In other words, upper portions of the barrier layer 130a on the sidewalls of the openings 115 may have a different thickness as compared to lower portions of the barrier layer 130a on the sidewall of the openings 115. In this respect it is noted that thickness refers to a distance as measured along a horizontal direction, i.e., a direction perpendicular to a direction of the openings 115, from an inner surface of the barrier layer 130a, i.e., a surface defining an interface with a side surface of the insulation layer pattern 120 in an opening 115, to an opposite surface of the barrier layer 130a, i.e., an outer surface adjacent to the inner surface and facing the opening 115. For example, as illustrated in FIG. 2, an upper portion of the barrier layer 130a on a sidewall of the openings 115 may be thicker than a lower portion of the barrier layer 130a on the sidewall of the openings 115. For example, as further illustrated in FIG. 2, a thickness of each portion of the barrier layer 130 on a sidewall of an opening 115 may gradually and uniformly decrease from the upper surface of the insulation layer pattern 120 to the lower surface of the insulation layer pattern 120. Portions of the barrier layer 130a on facing sidewalls of a single opening 115 may be symmetrical with respect to a vertical axis through a center of the single opening 115, i.e., the vertical axis being normal to the substrate 100.

Accordingly, an uppermost edge of a portion of the barrier layer 130a on a sidewall of an opening 115 may be thicker than a lowermost edge of the same portion of the barrier layer 130a. A thickness ratio between uppermost edges and lowermost edges of the barrier layer 130a may be about 1:3 to about 1:6. The thickness ratio between uppermost edges and lowermost edges of the barrier layer 130a on sidewalls of the opening 115 in a peripheral region of the substrate 100 may be larger as compared to the thickness ration in a cell region. For example, if the uppermost edge of the barrier layer 130a has a thickness of about 120 angstroms to about 250 angstroms, the lowermost edge of the barrier layer 130a may have a thickness of about 40 angstroms to about 80 angstroms.

As further illustrated in FIG. 2, a metal layer 135a may be formed on the barrier layer 130a, such that the metal layer 135a may be on the upper surface of the insulation layer pattern 120 and may fill up the openings 115. Due to the non-uniform thickness of the barrier layer 130a in the openings 115, the metal layer 135a may have a non-uniform width along the horizontal direction in the openings 115. For example, as illustrated in FIG. 2, the width of the metal layer 135a in each opening 115 may gradually and uniformly increase from the upper surface of the insulation layer pattern 120 to the lower surface of the insulation layer pattern 120. The metal layer 135a may include, e.g., tungsten, aluminum, copper, copper alloy, and so forth. The metal layer 135a may be formed by, e.g., an electroplating process or an electroless plating process.

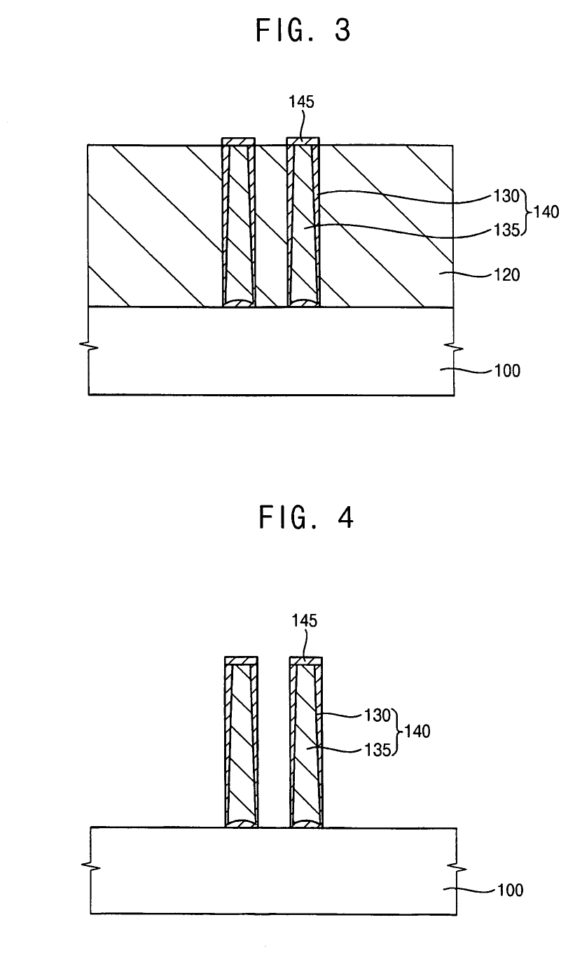

Referring to FIG. 3, a chemical mechanical polishing (CMP) process may be performed on the metal layer 135a and on the barrier layer 130a to expose the upper surface of the insulation layer pattern 120. In other words, portions of the metal layer 135a and of the barrier layer 130a above the upper surface of the insulation layer pattern 120 may be removed, such that portions of the metal layer 135a and of the barrier layer 130a may remain only in the openings 115 to define a metal layer pattern 135 and a barrier layer pattern 130, respectively. Each metal layer pattern 135 with a barrier layer pattern 130 may define a metal wire 140 in a respective opening 115. As described previously regarding the barrier layer 130a with reference to FIG. 2, a lowermost edge of the barrier layer pattern 130 may be thinner than an uppermost edge of the barrier layer pattern 130 along each sidewall of each opening 115.

As further illustrated in FIG. 3, a protective layer 145 may be formed on the metal wires 140. For example, the protective layer 145 may be formed on an upper surface of each metal wire 140 to completely cover upper surfaces of the metal layer pattern 135 and the barrier layer pattern 130, such that the protective layer 145 and the upper surface of the metal wire 140 may completely overlap. The protective layer 145 may prevent or substantially minimize damage to the metal wire 140 during removal of the insulation layer pattern 120 from the substrate 100 as will be described in more detail below with reference to FIG. 4. The protective layer 145 may include metal, e.g., one or more of tungsten (W), cobalt (Co), nickel (Ni), nickel phosphate (NiP), nickel tungsten phosphate (NiWP), nickel rhenium phosphate (NiReP), cobalt phosphate (CoP), cobalt tungsten phosphate (CoWP), copper phosphate (CuP), copper nickel phosphate (CuNiP), cobalt copper phosphate (CoCuP), cobalt tungsten (CoW), copper silicon nitride (CuSiN), and so forth.

The protective layer 145 may be formed, e.g., using an electroless plating method. More specifically, the substrate 100 may be dipped into a metal salt solution, so metallic ions are generated in the metal salt solution and reduced into an auto-catalyst by a reducing agent. As such, the metallic ions may be extracted onto the upper surface of the metal wire 140 without external electrical energy, so that metallic molecules may be generated on the upper surface of the metal wire 140 to form the protective layer 145. Accordingly, the protective layer 145 may have a compact texture and a substantially uniform surface on the metal wire 140. The metal salt solution may include a reducing agent, e.g., formaldehyde, hydrazine, and so forth, and may generate metallic ions including, e.g., one or more of W, CoP, CoW, Co, Ni, CoWP, and so forth.

Formation of the protective layer 145 on the metal wire 140 by the electroless plating method may be advantageous because the metallic molecules may be selectively deposited only on the metal wire 140, so the protective layer 145 may be formed only on the metal wire 140. In other words, as opposed to a conventional process, e.g., PVD or CVD, the metallic molecules may be deposited on the metal wire 140 without being in direct contact with the insulation layer pattern 120, thereby eliminating a need in an additional process for removing an unnecessary portion of the protective layer 145 from the insulation layer pattern 120.

Referring to FIG. 4, the insulation layer pattern 120 may be removed by an etching process using, e.g., an etching vapor. For example, the etching vapor may include hydrogen fluoride vapor, so the insulation layer pattern 120 may have a relatively high etch rate, and the barrier layer pattern 130 of the metal wire 140 may have a relatively low etch rate.

If hydrogen fluoride vapor is used, the etching process may be performed as follows. The substrate 100 with the insulation layer pattern 120 may be placed into an etching chamber, and the hydrogen fluoride vapor may be provided into the etching chamber as an etching gas to remove the insulation layer pattern 120. The insulation layer pattern 120 may be removed from the substrate 100 before the relatively thin lowermost edges of the barrier layer pattern 130, thereby minimizing damage to the barrier layer pattern 130. A thickness ratio of lowermost edges to uppermost edges of the barrier layer pattern 130 may be about 1:5 to about 1:9 after the insulation layer pattern 120 is removed. For example, when the uppermost edges have an initial thickness of about 160 angstroms and the lowermost edges have an initial thickness of about 40 angstroms, the uppermost edges may have a thickness of about 135 angstroms and the lowermost edges may have a thickness of about 20 angstroms after the insulation layer pattern 120 is removed.

The hydrogen fluoride vapor may be provided with a carrier gas, e.g., nitrogen gas, argon gas, and so forth, at a flow rate ratio of the hydrogen fluoride vapor to the carrier gas of about 1:5 to about 1:150, e.g., about 1:10 to about 1:100. For example, when the hydrogen fluoride vapor is provided into the etching chamber at a flow rate of about 0.1 SLM (standard liters per minute) to about 2 SLM, the carrier gas may be provided at a flow rate of about 10 SLM to about 80 SLM. When the flow rate ratio of the hydrogen fluoride vapor to the carrier gas is higher than the above ratio, the insulation layer pattern 120 may be damaged. When the flow rate ratio of the hydrogen fluoride vapor to the carrier gas is lower than the above ratio, removal time of the insulation layer pattern 120 may be substantially increased.

Each of the hydrogen fluoride vapor and the carrier gas may be provided at a temperature of about 25° C. to about 50° C. Accordingly, the etching process using the hydrogen fluoride vapor may be performed at a temperature of about 25° C. to about 50° C.

It is further noted that an etching solution may not be used in the etching process to prevent or substantially minimize surface tension between adjacent metal wires 140, thereby preventing or substantially minimizing inclination of the metal wires 140 toward each other. Accordingly, even when the distance between adjacent metal wires 140 is substantially small, e.g., about 80 nm or smaller, inclination of the metal wires 140 may not occur. It is further noted that etching with hydrogen fluoride vapor according to embodiments of the present invention may be substantially faster, i.e., provide a faster removal rate of the insulation layer pattern 120, as compared to a conventional dry-etching, thereby substantially minimizing damage to the metal wires 140 due to long exposure to dry-etching.

Method of Forming a Metal Wire of a Semiconductor Device

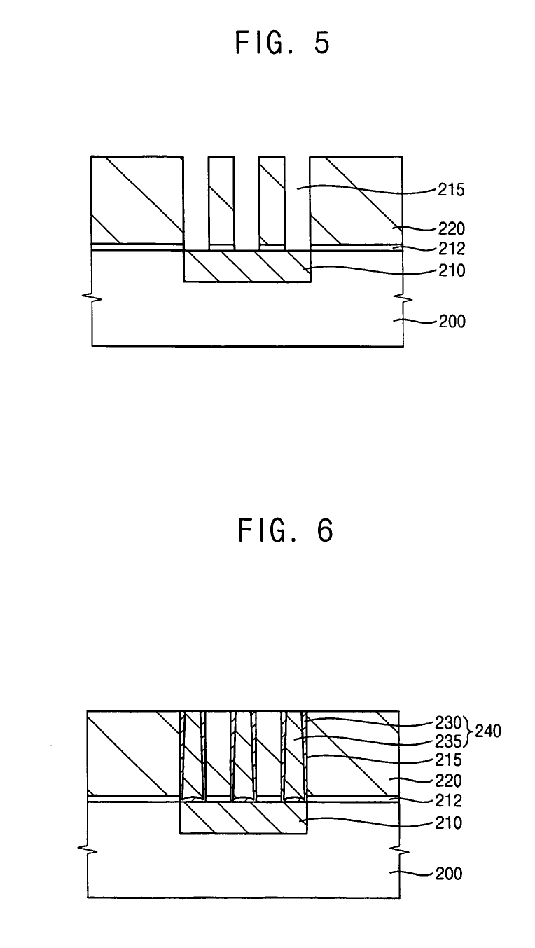

FIGS. 5-11 illustrate cross-sectional views of a method of forming metal wires of a semiconductor device in accordance with example embodiments of the present invention. Formation of the metal wires according to embodiments of the present invention may include removal of an insulation layer as described previously with reference to FIGS. 1-4.

Referring to FIG. 5, a substrate 200 having a lower structure 210 may be provided. The lower structure 210 may be a conductive structure, and may include, e.g., a transistor and a capacitor of a dynamic random access memory (DRAM) device, a switching element and phase-change material structure of a phase-change random access memory (PRAM) device, a selection transistor and a memory cell of a NAND flash memory device, and so forth. The transistor of the DRAM device or the selection transistor of the NAND flash memory device may have a multilayer structure including a sequentially stacked gate insulation layer and a gate electrode. The memory cell may include a multilayer structure in which a tunnel insulation layer, a floating gate, a dielectric layer, and a control gate are sequentially stacked.

An etch-stop layer (not shown), a first insulation layer (not shown), and an etching mask may be sequentially formed on the substrate 200 having the lower structure 210. The first insulation layer may be formed using an insulating material having a low dielectric constant. A detailed description of the etch-stop layer, first insulation layer, and etching mask may be substantially similar to the etch-stop layer, insulation layer, and etching mask described previously with reference to FIGS. 1-4, and therefore, their detailed description will not be repeated.

After the etching mask is formed on the first insulation layer, the first insulation layer and the etch-stop layer may be partially etched to expose an upper surface of the lower structure 210. Accordingly, the first insulation layer may be patterned into a first insulation layer pattern 220 having first openings 215 exposing the lower structure 210, and the etch-stop layer may be patterned into an etch-stop layer pattern 212. A distance between adjacent first openings 215 may be about 100 nm or less.

Referring to FIG. 6, first metal wires 240 including first barrier layer patterns 230 and first metal layer patterns 235 may be formed in the first openings 215. In particular, a first barrier layer (not shown) may be formed on a portion of the lower structure 210 exposed by the first openings 215, on sidewalls of the first insulation layer pattern 220, and on an upper surface of the first insulation layer pattern 220, such that a lower portion of the first barrier layer may have a thickness different from a thickness of the upper portion of the first barrier layer. A first metal layer (not shown), e.g., a layer including copper or copper alloy, may be formed on the first barrier layer to fill up the first openings 215. The first barrier layer and the first metal layer may be substantially similar to the barrier layer 130a and the metal layer 135a described previously with reference to FIGS. 1-4, and therefore, their detailed description will not be repeated.

The first metal layer and the first barrier layer may be polished by a CMP process to expose an upper surface of the first insulation layer pattern 220, thereby forming a first barrier layer pattern 230 and a first metal layer pattern 235 in each first opening 215. A lower portion of the first barrier layer pattern 230 may be thinner than an upper portion thereof as described above. The first barrier layer pattern 230 and the first metal layer pattern 235 in each first opening 215 may define a first metal wire 240 in each first opening 215. For example, as illustrated in FIG. 6, a plurality of metal wires 240 may be formed in the first insulation layer pattern 220, such that a region including the plurality of metal wires 240 may completely overlap the lower structure 210 of the substrate 200.

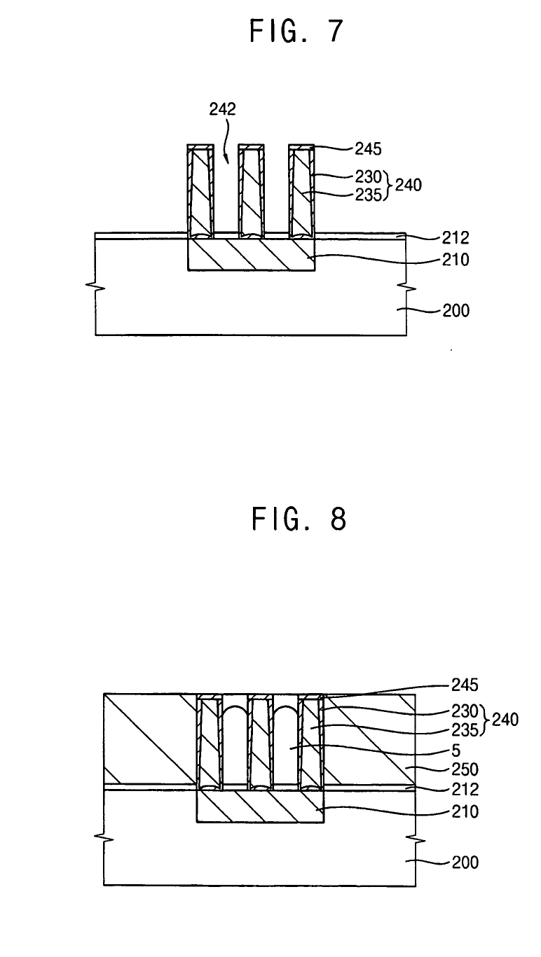

Referring to FIG. 7, a protective layer 245 including metal may be formed on the metal wires 240 to prevent or substantially minimize damage to the metal wires 240 during subsequent removal of the first insulation layer pattern 220. Next, the first insulation layer pattern 220 may be removed, such that the metal wires 240 with the protective layers 245 may extend vertically in an upward direction from the lower portion 210 of the substrate 200, as illustrated in FIG. 7. A space 242 may be formed between adjacent metal wires 240, as further illustrated in FIG. 7. The metal wires 240 and the protective layers 245 may be substantially similar to the metal wires 140 and the protective layers 145 described previously with reference to FIGS. 1-4, and therefore, detailed description, e.g., of their composition, structure, method of formation, and so forth, will not be repeated. It is further noted that removal of the first insulation layer pattern 220 may be substantially similar to the removal of the insulation layer pattern 120 described previously with reference to FIGS. 1-4, and therefore, its detailed description will not be repeated.

Referring to FIG. 8, an insulating material having a low dielectric constant may be deposited on the substrate 200 to form a second insulation layer 250 having voids 5 between the metal wires 240. In particular, the insulating material may be deposited on the substrate 200 by a CVD process, such that upper portions of the spaces 242 may be sealed with the insulating material. Since the insulating material is deposited only in upper portions of the spaces 242, lower portions of the spaces 242 may define the voids 5. Each void 5 between two adjacent metal wires 240 may reduce a parasitic capacitance between the adjacent metal wires 240. The second insulation layer 250 may be planarized to expose an upper surface of the protective layers 245 on the metal wires 240.

The second insulation layer 250 may be formed using, e.g., one or more of hydrogen silsesquioxane (HSQ), methyl silsesquioxane (MSQ), porous hydrogen silsesquioxane (P-HSQ), porous methyl silsesquioxane (P-MSQ), carbon-doped oxide (CDO), organosilicate glass (OSG), silicon carbide (SiC), silicon oxycarbide (SiOC), carbon-doped silicon oxide (SiCOH), and so forth. For example, the second insulation layer 250 may be formed by a CVD process using SiOC. In a more specific example, the second insulation layer 250 may be formed by a CVD process using a precursor, e.g., phenyltrimethoxysilane (C₆H₅Si(OCH₃)₂; PTMSM), trimethylsilane (Si(CH₃)₄; TMS), bis(trimethylsilyl)methane (H₉C₃-S₁-CH₂-S₁-C₃H₉), and so forth, and a carrier gas, e.g., argon gas, helium gas, and so forth, and the precursor may be reacted with oxygen gas.

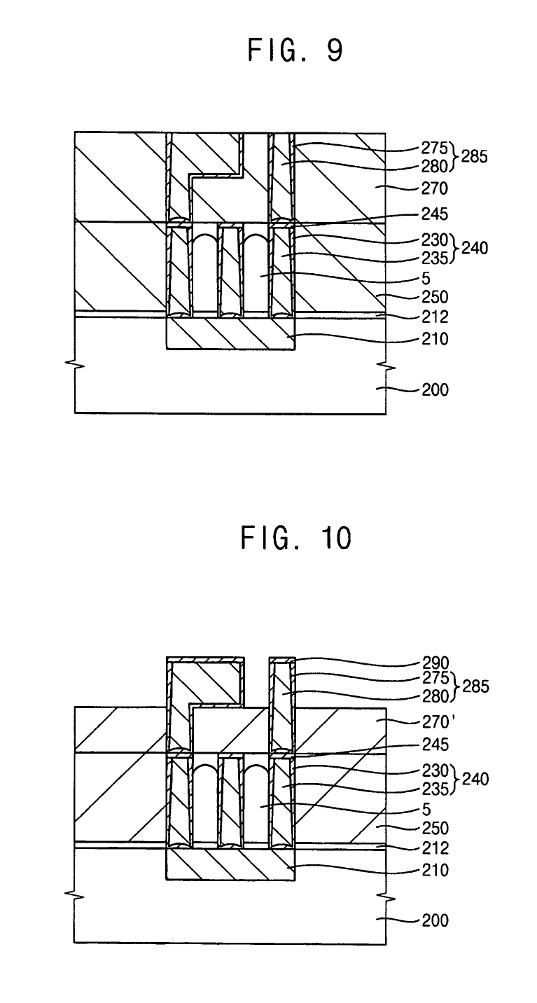

Referring to FIG. 9, a third insulation layer pattern 270 having second openings (not shown) exposing the first metal wires 240 may be formed on the second insulation layer 250. The second openings may have a variety of shapes, and may be formed by any suitable process used for forming openings for metal wires. A second metal layer pattern 280 may be formed in each second opening, such that a second barrier layer pattern 275 may be deposited in each second opening between the third insulation layer pattern 270 and the second metal layer pattern 280. Accordingly, the metal layer pattern 280 and the second barrier layer pattern 275 in each second opening may define a second metal wire 285 in each second opening.

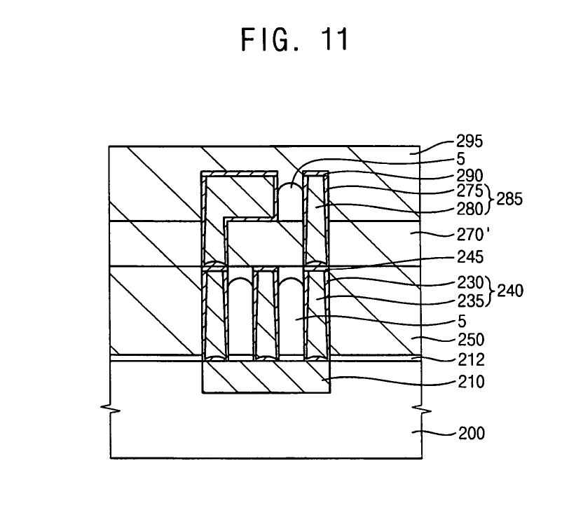

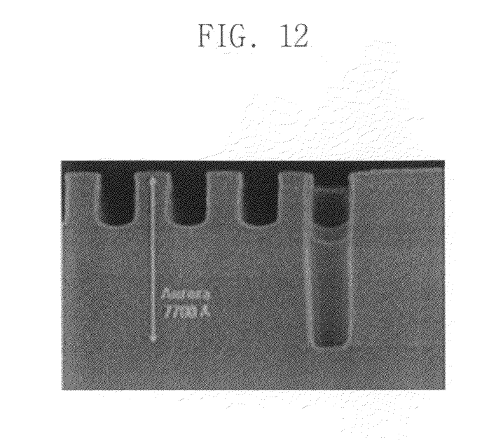

Referring to FIG. 10, a second protective layer 290 may be formed on the second metal wires 285 to prevent or substantially minimize damage to an upper portion of the second wire 285 during subsequent removal of a portion of the third insulation layer pattern 270. For example, the second protective layer 290 may be formed by an electroless plating method as described previously with reference to the first protective layer 245.

As further illustrated in FIG. 10, an upper portion of the third insulation layer pattern 270 may be removed by a second etching process using, e.g., a hydrogen fluoride vapor. Accordingly, only a lower portion of the third insulation layer pattern 270 may remain, and may define an etched insulation pattern layer 270′. In the second etching process using the hydrogen fluoride vapor, the third insulation layer pattern 270 may have a relatively high etch rate, while the second barrier layer pattern 275 may have a relatively low etch rate. Accordingly, the upper portion of the third insulation layer pattern 270 may be removed before the second barrier layer pattern 275 and the second protective layer 290 are damaged by the second etching process.

Referring to FIG. 11, after removing the upper portion of the third insulation layer pattern 270, an insulating material having a low dielectric constant may be deposited on an upper surface of the etched insulation pattern layer 270′ to form a fourth insulation layer 295 having a void 5 between the adjacent second metal wires 285.

### EXAMPLES

### Measurement of Removal Ability of a FOx Insulation Layer

### Example 1

a FOx insulation layer was formed on a substrate to fill up an opening to a thickness of 4,700 angstroms, followed by formation of an FSG insulation layer on the FOx insulation layer to fill up an opening to a thickness of 1,000 angstroms. Next, the FOx insulation layer and the FSG insulation layer were etched for 5 seconds using a hydrogen fluoride vapor at a flow rate of 0.8 SLM and a nitrogen gas at a flow rate of 24 SLM. As a result, the FOx insulation layer and the FSG insulation layer were removed from the substrate.

### Comparative Example 1

a FOx insulation layer was formed on a substrate to fill up an opening to a thickness of 4,700 angstroms, followed by formation of an FSG insulation layer on the FOx insulation layer to fill up an opening to a thickness of 1,000 angstroms. Next, the FOx insulation layer and the FSG insulation layer were wet-etched for twenty seconds using a limulus amebocyte lysate (LAL) etching solution including ammonium fluoride (NH₄F), hydrogen fluoride (HF), and water. As a result, the FOx insulation layer filling up the opening was removed but the FSG insulation layer was hardly removed.

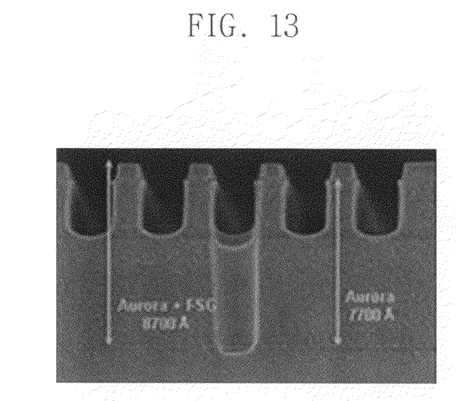

FIGS. 12-13 illustrate scanning electron microscope (SEM) photographs of substrates treated according to Example 1 and Comparative Example 1, respectively. As illustrated in FIGS. 12-13, the etching process using a hydrogen fluoride vapor, i.e., Example 1, exhibited a higher etching ratio with respect to the FSG insulation layer than the wet etching of Comparative Example 1. Further, as illustrated by the arrows in FIGS. 12-13, portions etched by wet etching, i.e., Comparative Example 1, were inclined with respect to a normal to the substrate. Referring to Example 1 and Comparative Example 1, the etching process using a hydrogen fluoride vapor exhibited a removal rate of the FOx insulation layer that was about four times higher that the removal rate of the FOx insulation layer by the wet etching process using a LAL etching solution, i.e., Comparative Example 1.

A method of removing an insulation layer covering metal wires according to embodiments of the present invention may be advantageous by using hydrogen fluoride vapor, thereby preventing or substantially minimizing damage to a barrier layer of the metal wires during etching. As such, the metal wires may not be damaged when the insulation layer is completely removed.

More specifically, removal of an insulation layer surrounding metal wires according to embodiments of the present invention may prevent use of an etching solution, i.e., a solution used in a wet etching, thereby preventing or substantially minimizing contact between adjacent metal wires due to a capillary phenomenon triggered by use of a conventional etching solution in wet etching. Further, removal of an insulation layer surrounding metal wires according to embodiments of the present invention may exhibit a substantially fast etching rate. It is further noted that when a metal silicide layer and a tungsten plug are formed in-situ using an electroless plating method and a tungsten source gas as a source gas, tungsten may not be diffused into the substrate.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of removing an insulation layer pattern covering metal wires, comprising:
providing an insulation layer pattern on a substrate, the insulation layer pattern having openings exposing the substrate;
forming metal wires in the openings by depositing a barrier layer on inner surfaces of the openings, such that a lower portion of the barrier layer is thinner that an upper portion of the barrier layer, and depositing a metal layer to fill the openings; and
performing an etching process with an etching vapor to remove the insulation layer pattern from the substrate to expose the metal wires.

2. The method as claimed in claim 1, wherein performing the etching process with the etching vapor includes using a hydrogen fluoride vapor.

3. The method as claimed in claim 1, wherein providing the insulation layer pattern includes depositing on the substrate a layer of one or more of a silicon dioxide (Si O₂), a fluorosilicate glass (FSG), a tetraethyl orthosilicate (TEOS) oxide, a silanol (SiOH), a flowable oxide (FOx), a bottom anti-reflective coating (BARC), an anti-reflective coating (ARC), a photoresist (PR), a near-frictionless carbon (NFC), a silicon carbide (SiC), a silicon oxycarbide (SiOC), and a carbon-doped silicon oxide (SiCOH).

4. The method as claimed in claim 1, further comprising forming an etch-stop layer on the substrate before forming the insulation layer pattern.

5. The method as claimed in claim 1, wherein forming the metal wires includes,
forming the barrier layer on inner sidewalls of the openings and on the insulation layer pattern;
forming the metal layer pattern on the barrier layer to completely fill the openings and cover the insulation layer pattern; and
performing a chemical mechanical polishing (CMP) process to remove portions of the metal layer pattern and the barrier layer to expose an upper surface of the insulation layer pattern.

6. The method as claimed in claim 5, wherein forming the barrier layer includes depositing one or more of titanium/titanium nitride (Ti/TiN), tantalum/tantalum nitride (Ta/TaN), and tungsten/tungsten nitride (W/WN).

7. The method as claimed in claim 1, wherein forming the barrier layer includes forming lowermost and uppermost edges of the barrier layer to have a thickness ratio of about 1:3 to about 1:6.

8. The method as claimed in claim 7, wherein after removing the insulation layer pattern the lowermost and uppermost edges of the barrier layer have a thickness ratio of about 1:5 to about 1:9.

9. The method as claimed in claim 1, further comprising forming a protective layer on the metal wires, the protective layer including one or more of tungsten (W), cobalt (Co), nickel (Ni), nickel phosphate (NiP), nickel tungsten phosphate (NiWP), nickel rhenium phosphate (NiReP), cobalt phosphate (CoP), cobalt tungsten phosphate (CoWP), copper phosphate (CuP), copper nickel phosphate (CuNiP), cobalt copper phosphate (CoCuP), cobalt tungsten (CoW), and copper silicon nitride (CuSiN).

10. The method as claimed in claim 9, wherein forming the protective layer includes using an electroless plating process.

11. The method as claimed in claim 1, wherein providing the insulation layer pattern with the openings includes forming the openings such that a distance between two adjacent openings is about 20 nm to about 90 nm.

12. The method as claimed in claim 1, wherein the etching process with the etching vapor is performed at a temperature of about 25° C. to about 50° C.

13. The method as claimed in claim 1, wherein the etching process with the etching vapor is performed by providing together a hydrogen fluoride gas as an etching gas and a nitrogen gas as a carrier gas.

14. The method as claimed in claim 13, wherein the etching process with the etching vapor includes providing the hydrogen fluoride gas and the nitrogen gas at a flow rate ratio of about 1:5 to about 1:300 SLM (standard liters per minute).

15. A method of forming metal wires, comprising:
forming a first insulation layer pattern on a substrate having a conductive pattern, the insulation layer pattern having openings exposing the conductive pattern;
forming a barrier layer on inner surfaces of the openings, such that a lower portion of the barrier layer is thinner than an upper portion of the barrier layer;
forming a metal layer to fill up the openings, the metal layer and the barrier layer defining first metal wires;
removing the first insulation layer pattern from the substrate by performing an etching process with an etching vapor to expose the first metal wires; and
forming a second insulation layer on the substrate and on the first metal wires, such that a void is formed between adjacent first metal wires.

16. The method of forming metal wires as claimed in claim 15, further comprising forming an etch-stop layer having a substantially uniform thickness between the substrate and the first insulation layer.

17. The method of forming metal wires as claimed in claim 15, further comprising forming a protective layer on the first metal wires.

18. The method as claimed in claim 15, wherein the etching process using the etching vapor is performed using a hydrogen fluoride gas as an etching gas and nitrogen gas as a carrier gas, hydrogen fluoride gas and the carrier gas having a flow rate ratio of about 1:5 to about 1:300 SLM (standard liters per minute).
